(19) United States
(12) Patent Application Publication
(10) Pub. No.: US 2024/0348004 A1
(43) Pub. Date: Oct. 17, 2024

(54) LASER DIODE DEVICE

(71) Applicant: ROHM CO., LTD., Kyoto-shi (JP)

(72) Inventor: Akito SHINODA, Kyoto-shi (JP)

(21) Appl. No.: 18/751,860

(22) Filed: Jun. 24, 2024

Related U.S. Application Data
(63) Continuation of application No. PCT/JP2022/035406, filed on Sep. 22, 2022.

(30) Foreign Application Priority Data
Dec. 22, 2021 (JP) 2021-208248

(51) Int. Cl. H01S 5/02326; H01S 5/02208; H01S 5/02345

(52) U.S. Cl. CPC H01S 5/02326; H01S 5/02208; H01S 5/02345

(57) ABSTRACT

A laser diode device includes a substrate, a mount, a laser diode chip, and a cover. The substrate includes a base material including a first main surface and a second main surface opposite to the first main surface, and a first conductor pattern arranged on the first main surface. The first main surface includes an outer peripheral region shaped like a ring. The first conductor pattern includes a terminal portion present inside the outer peripheral region in a plan view. The mount is arranged on the terminal portion and formed of a conductor. The laser diode chip is arranged over the mount. The laser diode chip includes a light emitting surface from which laser light is emitted to the outside of the substrate in a plan view.

### TECHNICAL FIELD

The present disclosure relates to a laser diode device.

### BACKGROUND ART

Japanese Patent Laying-Open No. 2020-144048 (PTL 1) describes a light source device. The light source device described in PTL 1 includes a substrate, a peripheral wall, a transparent member, a laser diode, and a reflection member. The peripheral wall is arranged on a main surface of the substrate. The transparent member is arranged on the peripheral wall. The transparent member is arranged on the peripheral wall.

The laser diode is arranged in a space defined by the substrate, the peripheral wall, and the transparent member. More specifically, the laser diode is arranged on the main surface of the substrate. The laser diode is an edge-emitting laser diode. That is, the side surface of the laser diode serves as the light emitting surface. The reflection member is arranged in the space defined by the substrate, the peripheral wall, and the transparent member. The laser light emitted from the light emitting surface of the laser diode is reflected off the reflection member and emitted to the outside through the transparent member.

### CITATION LIST

### Patent Literature

PTL 1: Japanese Patent Laying-Open No. 2020-144048

### BRIEF DESCRIPTION OF DRAWINGS

FIG. 1 is a plan view of a laser diode device 100.

FIG. 2 is a cross sectional view along II-II in FIG. 1.

FIG. 3 is a cross sectional view along III-III in FIG. 1.

FIG. 4 is a cross sectional view along IV-IV in FIG. 1.

FIG. 5 is a cross sectional view of a laser diode device 200.

FIG. 6 is a cross sectional view of a laser diode device 100A.

FIG. 7 is a cross sectional view of a laser diode device 100B.

FIG. 8 is a plan view of a laser diode device 300.

FIG. 9 is a cross sectional view along IX-IX in FIG. 8.

FIG. 10 is a plan view of a laser diode device 300A.

FIG. 11 is a cross sectional view along XI-XI in FIG. 10.

### DESCRIPTION OF EMBODIMENTS

Embodiments of the present disclosure are described with reference to the drawings. On the drawings, hereinafter, the same or corresponding portions are denoted by the same reference characters and overlapping descriptions are not repeated.

### Embodiment 1

A laser diode device according to Embodiment 1 is described. The laser diode device according to Embodiment 1 is referred to as laser diode device 100.

### <Configuration of Laser Diode Device 100>

Laser diode device 100 is described below.

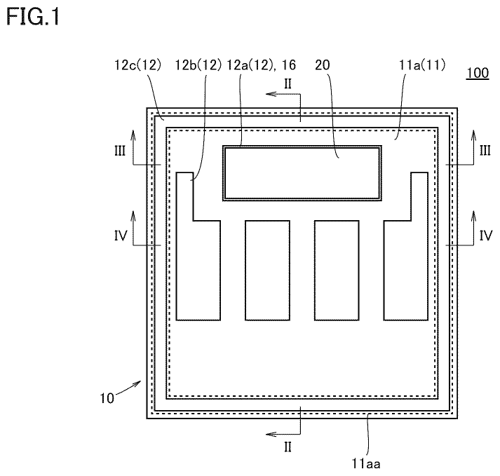

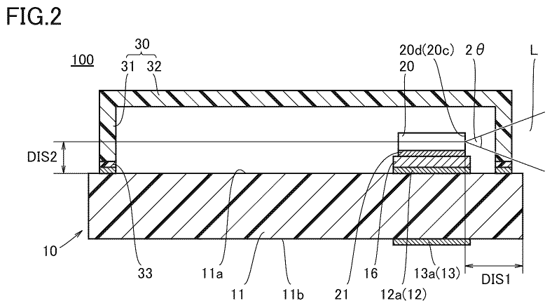

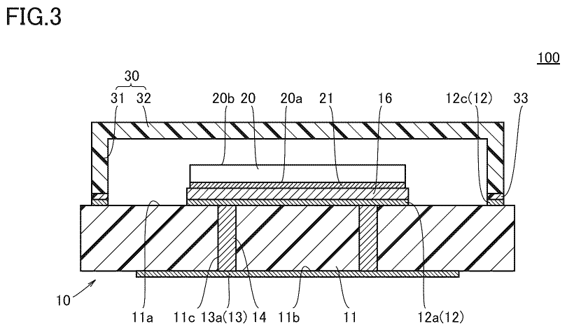

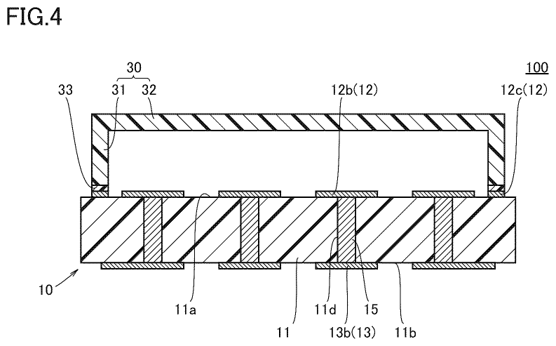

FIG. 1 is a plan view of laser diode device 100. In FIG. 1, a cover 30 is not illustrated. FIG. 2 is a cross sectional view along II-II in FIG. 1. FIG. 3 is a cross sectional view along III-III in FIG. 1. FIG. 4 is a cross sectional view along IV-IV in FIG. 1. As illustrated in FIGS. 1, 2, 3, and 4, laser diode device 100 includes a substrate 10, a laser diode chip 20, and cover 30.

Substrate 10 includes a base material 11, a conductor pattern 12, a conductor pattern 13, a conductor plug 14, and a conductor plug 15.

Base material 11 includes a first main surface 11a and a second main surface 11b. First main surface 11a and second main surface 11b are end surfaces in a thickness direction of base material 11. Second main surface 11b is the opposite surface of first main surface 11a. Base material 11 is formed from an electrically insulating material. Base material 11 is formed from, for example, glass epoxy. However, base material 11 may be formed from a different material from this. In a plan view, base material 11 is rectangular for example.

A region on the outer periphery of first main surface 11a is an outer peripheral region 11aa. In a plan view, outer peripheral region 11aa is shaped like a rectangular ring. Outer peripheral region 11aa may be present away from the outer peripheral edge of first main surface 11a. When laser diode device 100 does not include cover 30, first main surface 11a is not necessarily required to include outer peripheral region 11aa.

Conductor pattern 12 is arranged on first main surface 11a. Conductor pattern 12 is formed of a conductor. Conductor pattern 12 is formed of, for example, copper (Cu). Conductor pattern 12 includes a terminal portion 12a and a terminal portion 12b. Terminal portion 12a is, for example, a terminal for the cathode of laser diode chip 20. In a plan view, terminal portion 12a is rectangular. In a plan view, terminal portion 12b is present inside outer peripheral region 11aa. Terminal portion 12b is, for example, a terminal for the anode of laser diode chip 20. The number of terminal portions 12b is, for example, two or more. In the example illustrated in FIGS. 1 to 4, the number of terminal portions 12b is four.

Conductor pattern 12 may include a connection portion 12c. Connection portion 12c is arranged in outer peripheral region 11aa. In a plan view, connection portion 12c is shaped like a rectangular ring.

Conductor pattern 13 is arranged on second main surface 11b. Conductor pattern 13 is formed of a conductor. Conductor pattern 13 is formed of, for example, copper. Conductor pattern 13 includes a terminal portion 13a and a terminal portion 13b. In a plan view, terminal portion 13a and terminal portion 13b respectively overlap terminal portion 12a and terminal portion 12b, at least partially. The number of terminal portions 13b is equal to the number of terminal portions 12b.

In base material 11, a through hole 11c and a through hole 11d are formed. Through hole 11c and through hole 11d run through base material 11 along the thickness direction. In a plan view, through hole 11c overlaps both of terminal portion 12a and terminal portion 13a. In a plan view, through hole 11c and through hole 11d are, for example, circular. The number of through holes 11c may be two or more. In the example illustrated in FIGS. 1 to 4, the number of through holes 11c is two. The number of through holes 11d is equal to the number of terminal portions 12b (terminal portions 13b). In a plan view, through hole 11d overlaps both of terminal portion 12b and terminal portion 13b.

Conductor plug 14 and conductor plug 15 are each formed of a conductor. Conductor plug 14 and conductor plug 15 are formed of, for example, copper. Conductor plug 14 is embedded in through hole 11c. Accordingly, terminal portion 12a and terminal portion 13a are electrically connected. Conductor plug 15 is embedded in through hole 11d. Accordingly, terminal portion 12b and terminal portion 13b are electrically connected.

On terminal portion 12a, a mount 16 is arranged. Mount 16 is formed of a conductor. Mount 16 is formed of, for example, copper. Mount 16 is preferably formed by plating. That is, mount 16 is preferably a plating film. Mount 16 may be arranged on terminal portion 12b but is not necessarily required to be arranged on terminal portion 12b. Another plating film may be further arranged on mount 16. This plating film is, for example, a gold (Au) plating film. When mount 16 is not arranged on terminal portion 12b, this plating film is also arranged on terminal portion 12b.

Laser diode chip 20 is arranged over mount 16 with a connection layer 21 interposed therebetween. Thus, laser diode chip 20 is present inside outer peripheral region 11aa in a plan view. Connection layer 21 is formed of, for example, a conductive adhesive.

Laser diode chip 20 includes a bottom surface 20a, an upper surface 20b, and a plurality of side surfaces 20c. Laser diode chip 20 is arranged over mount 16 so that bottom surface 20a is opposite to mount 16 with connection layer 21 interposed therebetween.

A cathode electrode (not illustrated) of laser diode chip 20 is provided on bottom surface 20a. The cathode electrode of laser diode chip 20 is electrically connected to mount 16 and terminal portion 12a via connection layer 21. An anode electrode (not illustrated) of laser diode chip 20 is provided on upper surface 20b. The number of anode electrodes of laser diode chip 20 is equal to the number of terminal portions 12b. The anode electrode of laser diode chip 20 is electrically connected to terminal portion 12b via a bonding wire (not illustrated).

Side surface 20c is contiguous to both of bottom surface 20a and upper surface 20b. One of the plurality of side surfaces 20c is a light emitting surface 20d of laser diode chip 20. Laser light L (see FIG. 2) is emitted from light emitting surface 20d. That is, laser diode chip 20 is an edge-emitting laser diode. In a plan view, laser diode chip 20 emits laser light L from light emitting surface 20d to the outside of substrate 10.

The distance between light emitting surface 20d and the outer peripheral edge of substrate 10 (base material 11) closest to light emitting surface 20d in a plan view is referred to as a distance DIS1. The distance between a position on light emitting surface 20d at which laser light L is emitted and first main surface 11a is referred to as a distance DIS2. Laser light L extends in up and down directions at an angle of 2θ. The thickness of mount 16 is determined so that distance DIS2 is larger than distance DIS1×tan θ.

Cover 30 includes a side wall 31 and an upper wall 32. In a plan view, side wall 31 is shaped like a rectangular ring. Cover 30 is attached to outer peripheral region 11aa at a lower end of side wall 31. More specifically, a connection layer 33 connects the lower end of side wall 31 to connection portion 12c. Connection layer 33 is formed of an adhesive. Upper wall 32 is contiguous to an upper end of side wall 31. Thus, cover 30 is constructed like a box. Cover 30 is formed from a light-transparent resin material that allows laser light L to pass therethrough. Cover 30 is formed from, for example, epoxy resin. Laser light L that has been emitted from light emitting surface 20d passes through cover 30 and is emitted to the outside of laser diode device 100.

### <Effects of Laser Diode Device 100>

Effects of laser diode device 100 are described below in comparison with a laser diode device according to a comparative example. The laser diode device according to the comparative example is referred to as laser diode device 200.

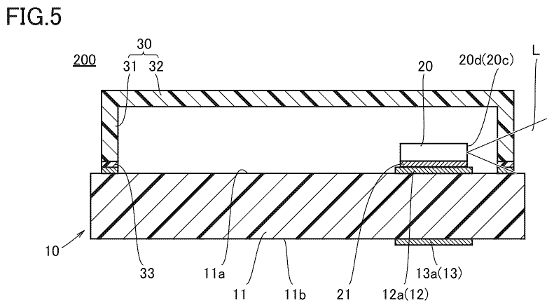

FIG. 5 is a cross sectional view of laser diode device 200. FIG. 5 illustrates a cross section of laser diode device 200 in a position corresponding to II-II in FIG. 1. As illustrated in FIG. 5, the configuration of laser diode device 200 is common to the configuration of laser diode device 100 except that laser diode device 200 does not include mount 16.

In laser diode device 200, it is unavoidable to arrange a terminal portion 12a inside an outer peripheral region 11aa in a plan view since a cover 30 (a lower end of a side wall 31) is attached to outer peripheral region 11aa. Accordingly, in laser diode device 200, the value of a distance DIS1×tan θ is larger than a distance DIS2 and as a result, laser light L is partially obstructed by a substrate 10 (a base material 11).

Also in laser diode device 100, it is unavoidable to arrange terminal portion 12a inside outer peripheral region 11aa in a plan view since cover 30 is attached to outer peripheral region 11aa. However, in laser diode device 100, mount 16 is arranged on terminal portion 12a and laser diode chip 20 is arranged over mount 16. Accordingly, distance DIS2 can be made larger than distance DIS1×tan θ. Thus, in laser diode device 100, laser light L emitted from light emitting surface 20d can be hindered from getting obstructed by substrate 10.

When mount 16 is a plating film in laser diode device 100, mount 16 can be formed easily.

### <Variation 1>

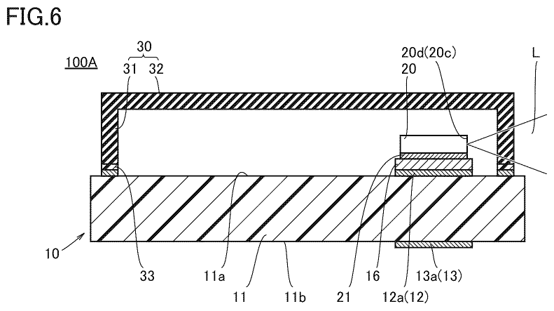

Laser diode device 100 according to Variation 1 is referred to as laser diode device 100A. FIG. 6 is a cross sectional view of laser diode device 100A. FIG. 6 illustrates a cross section of laser diode device 100A in the position corresponding to II-II in FIG. 1. As illustrated in FIG. 6, in laser diode device 100A, cover 30 is formed of glass. The glass that forms a part included in side wall 31 and facing light emitting surface 20d is preferably larger in the transmittance for laser light L than the glass that forms a part included in side wall 31 and not facing light emitting surface 20d and forms upper wall 32. The transmittance of the glass that forms the part included in side wall 31 and facing light emitting surface 20d with respect to laser light L is 99% or more for example.

### <Variation 2>

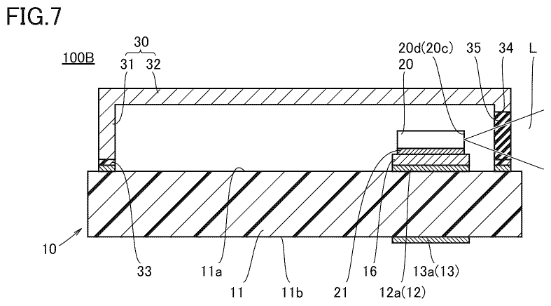

Laser diode device 100 according to Variation 2 is referred to as laser diode device 100B. FIG. 7 is a cross sectional view of laser diode device 100B. FIG. 7 illustrates a cross section of laser diode device 100B in the position corresponding to II-II in FIG. 1. As illustrated in FIG. 7, in laser diode device 100B, cover 30 is formed of a metal material.

In laser diode device 100B, an opening 34 is formed in a part included in side wall 31 and facing light emitting surface 20d. Opening 34 is closed with a glass member 35. Glass member 35 is formed of a glass material that allows laser light L to pass therethrough. Opening 34 is not necessarily required to be closed with glass member 35. In laser diode device 100B, heat resistance can be enhanced since cover 30 is formed of a metal material.

### Embodiment 2

A laser diode device according to Embodiment 2 is described. The laser diode device according to Embodiment 2 is referred to as laser diode device 300.

Hereinafter, differences from laser diode device 100 are mainly described and overlapping descriptions are not repeated.

### <Configuration of Laser Diode Device 300>

A configuration of laser diode device 300 is described below.

Laser diode device 300 includes a substrate 10, a laser diode chip 20, a cover 30, and a bonding wire (not illustrated). In laser diode device 300, substrate 10 includes a conductor pattern 12, which includes a terminal portion 12a, a terminal portion 12b, and a connection portion 12c, a conductor pattern 13, which includes a terminal portion 13a and a terminal portion 13b, and a conductor plug 14 and a conductor plug 15, which are respectively embedded in a through hole 11c and a through hole 11d formed in a base material 11.

In laser diode device 300, a mount 16 is arranged on terminal portion 12a and laser diode chip 20 is arranged over mount 16. In these respects, the configuration of laser diode device 300 is common to the configuration of laser diode device 100.

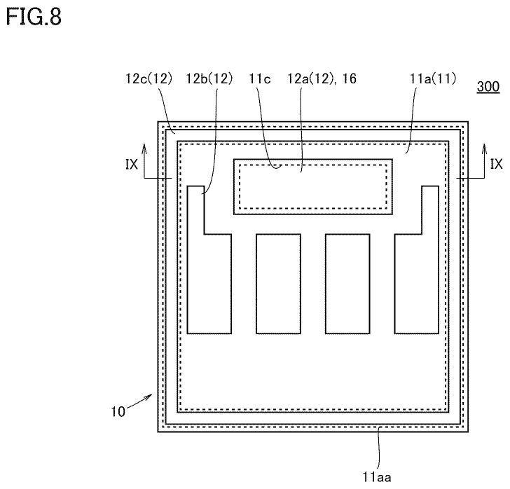

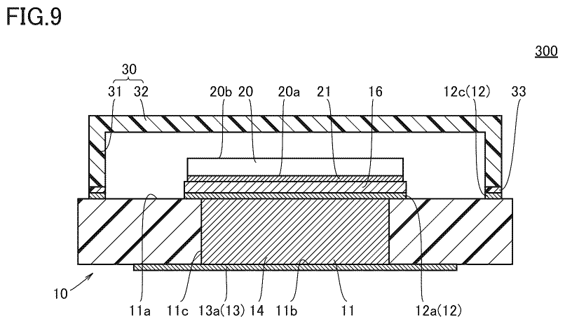

FIG. 8 is a plan view of laser diode device 300. In FIG. 8, laser diode chip 20, a connection layer 21, and cover 30 are not illustrated. FIG. 9 is a cross sectional view along IX-IX in FIG. 8. As illustrated in FIGS. 8 and 9, in laser diode device 300, the number of through holes 11c is one. In laser diode device 300, through hole 11c is rectangular in a plan view. In laser diode device 300, the opening area of through hole 11c in a plan view is 50% or more and 100% or less of the area of terminal portion 12a in a plan view. In these respects, the configuration of laser diode device 300 is different from the configuration of laser diode device 100.

### <Effects of Laser Diode Device 300>

Effects of laser diode device 300 are described below.

In laser diode device 300, the opening area of through hole 11c in a plan view is 50% or more and 100% or less of the area of terminal portion 12a in a plan view, and the area of conductor plug 14 in a plan view is also large. Thus, in laser diode device 300, heat generated in laser diode chip 20 can be easily dissipated through conductor plug 14.

### <Variation>

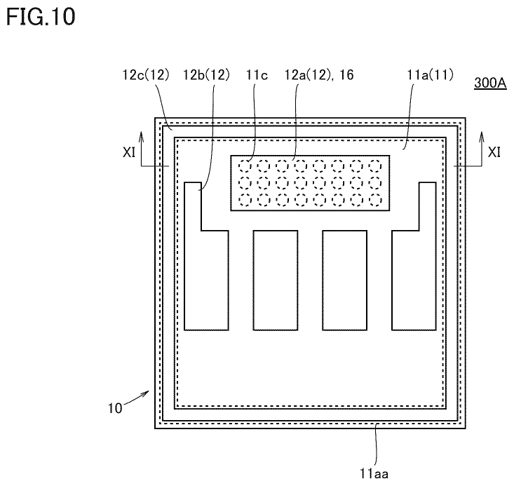

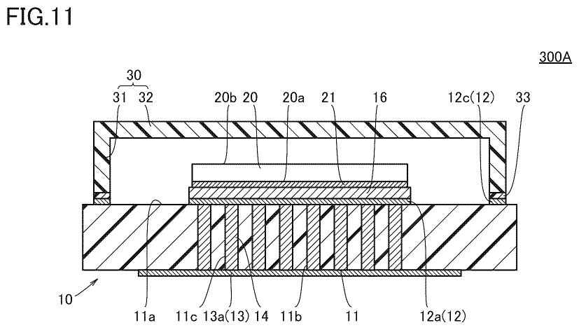

Laser diode device 300 according to a variation is referred to as laser diode device 300A. FIG. 10 is a plan view of laser diode device 300A. In FIG. 10, laser diode chip 20, connection layer 21, and cover 30 are not illustrated. FIG. 11 is a cross sectional view along XI-XI in FIG. 10. As illustrated in FIGS. 10 and 11, in laser diode device 300A, a plurality of through holes 11c are arranged in a matrix in a plan view. In laser diode device 300A, the total of the opening areas of the plurality of through holes 11c in a plan view is preferably 50% or more of the area of terminal portion 12a in a plan view.

In laser diode device 300A, the plurality of through holes 11c are arranged in a matrix in a plan view, and the total of the areas of a plurality of conductor plugs 14 in a plan view is large. Thus, in laser diode device 300A, heat generated in laser diode chip 20 can be easily dissipated through the plurality of conductor plugs 14.

Further, in laser diode device 300A, base material 11 is present between two conductor plugs 14 adjacent to each other. Accordingly, thermal expansion of conductor plug 14 is inhibited in comparison with the case in which conductor plug 14 is embedded in one through hole 11c having a large opening area. Thus, in laser diode device 300A, occurrence of a crack in connection layer 21 can be inhibited, which is caused by a difference between the thermal expansion of conductor plug 14 and the thermal expansion of laser diode chip 20.

Although embodiments of the present disclosure are described above, the above-described embodiments can be changed variously. In addition, the scope of the present invention is not limited to the above-described embodiments. The scope of the present invention is defined by the claims and intended to include all changes within the purport and scope equivalent to the claims.

### REFERENCE SIGNS LIST

100 laser diode device; 10 substrate; 11 base material; 11a first main surface; 11aa outer peripheral region; 11b second main surface; 11c, 11d through hole; 12 conductor pattern; 12a, 12b terminal portion; 12c connection portion; 13 conductor pattern; 13a, 13b terminal portion; 14, 15 conductor plug; 16 mount; 20 laser diode chip; 20a bottom surface; 20b upper surface; 20c side surface; 20d light emitting surface; 21 connection layer; 30 cover; 31 side wall; 32 upper wall; 33 connection layer; 34 opening; 35 glass member; 100A, 100B, 200, 300, 300A laser diode device; DIS1, DIS2 distance; L laser light.

1. A laser diode device comprising:
a substrate;
a mount;
a laser diode chip; and
a cover, wherein
the substrate includes a base material and a first conductor pattern, the base material including a first main surface and a second main surface that is an opposite surface of the first main surface, the first conductor pattern being arranged on the first main surface,
the first main surface includes an outer peripheral region shaped like a ring,
the first conductor pattern includes a terminal portion present inside the outer peripheral region in a plan view,
the mount is arranged on the terminal portion and formed of a conductor,
the laser diode chip is arranged over the mount,
the laser diode chip includes a light emitting surface from which laser light is emitted to an outside of the substrate in a plan view, and
the cover includes a side wall and is attached to the outer peripheral region at a lower end of the side wall.

2. The laser diode device according to claim 1, wherein the substrate is a glass epoxy substrate in which the base material is formed from glass epoxy.

3. The laser diode device according to claim 2, wherein the mount is a plating film.

4. The laser diode device according to claim 1, wherein the cover is formed from a light-transparent resin material allowing the laser light to pass therethrough.

5. The laser diode device according to claim 1, wherein a part included in the side wall and facing the light emitting surface is formed of glass allowing the laser light to pass therethrough.

6. The laser diode device according to claim 1, wherein
the cover is formed of a metal material, and
an opening is formed in a part included in the side wall and facing the light emitting surface.

7. The laser diode device according to claim 6, wherein the opening is closed with a glass member allowing the laser light to pass therethrough.

8. The laser diode device according to claim 1, wherein
the substrate includes a plurality of conductor plugs and a second conductor pattern,
a plurality of through holes running through the base material along a direction from the first main surface to the second main surface are formed in the base material,
the plurality of conductor plugs are respectively embedded in the plurality of through holes,
the second conductor pattern is arranged on the second main surface, and
the plurality of through holes are arranged in a matrix so as to overlap the terminal portion and the second conductor pattern in a plan view.

9. The laser diode device according to claim 1, wherein
the substrate includes a conductor plug and a second conductor pattern,
a through hole running through the base material along a direction from the first main surface to the second main surface is formed in the base material,
the conductor plug is embedded in the through hole,
the second conductor pattern is arranged on the second main surface,
the through hole is arranged so as to overlap the terminal portion and the second conductor pattern in a plan view, and
an opening area of the through hole in a plan view is 50% or more and 100% or less of an area of the terminal portion in a plan view.

10. A laser diode device comprising:
a substrate; and
a laser diode chip, wherein
the substrate includes a base material, a first conductor pattern, a second conductor pattern, and a plurality of conductor plugs, the base material including a first main surface and a second main surface that is an opposite surface of the first main surface, the first conductor pattern being arranged on the first main surface, the second conductor pattern being arranged on the second main surface,
the first conductor pattern includes a terminal portion,
the laser diode chip is arranged over the terminal portion,
a plurality of through holes running through the base material along a direction from the first main surface to the second main surface are formed in the base material,
the plurality of conductor plugs are respectively embedded in the plurality of through holes, and
the plurality of through holes are arranged in a matrix so as to overlap the terminal portion and the second conductor pattern in a plan view.

11. A laser diode device comprising:
a substrate; and
a laser diode chip, wherein
the substrate includes a base material, a first conductor pattern, a second conductor pattern, and a conductor plug, the base material including a first main surface and a second main surface that is an opposite surface of the first main surface, the first conductor pattern being arranged on the first main surface, the second conductor pattern being arranged on the second main surface,
the first conductor pattern includes a terminal portion,
the laser diode chip is arranged over the terminal portion,
a through hole running through the base material along a direction from the first main surface to the second main surface is formed in the base material,
the conductor plug is embedded in the through hole,
the through hole is arranged so as to overlap the terminal portion and the second conductor pattern in a plan view, and
an opening area of the through hole in a plan view is 50% or more and 100% or less of an area of the terminal portion in a plan view.
